(19) United States
(12) Patent Application Publication
(10) Pub. No.: US 2018/0320718 A1
(43) Pub. Date: Nov. 8, 2018

(54) TORQUE LIMITER WEDGES

(71) Applicant: Arconic Inc., Pittsburgh, PA (US)

(72) Inventor: Thai Do, Laguna Niguel, CA (US)

(73) Assignee: Arconic Inc., Pittsburgh, PA (US)

(21) Appl. No.: 15/968,395

(22) Filed: May 1, 2018

Related U.S. Application Data
(60) Provisional application No. 62/500,315, filed on May 2, 2017.

(51) Int. Cl. F16B 2/14; H05K 7/14

(52) U.S. Cl. CPC F16B 2/14; H05K 7/1417

(57) ABSTRACT

A device includes a body, a front wedge, a body wedge, a ratchet, an internal thread, a first end, a second end, and a longitudinal axis. The front wedge is positioned at the first end of the body. The body wedge has a first face and a second face and is positioned adjacent the front wedge and adjacent the body. Motion of the front wedge toward the second end of the body causes motion of the body wedge away from the body perpendicular to the longitudinal axis. The ratchet is positioned within the holes of the body the front wedge. Motion of the ratchet toward the second end of the body causes motion of the front wedge toward the second end of the body. Rotation of the ratchet about the longitudinal axis in a first direction causes the ratchet to move toward the second end of the body.

### CROSS-REFERENCE TO RELATED APPLICATION

This application is a Section 111(a) application relating to and claiming the benefit of commonly-owned, co-pending U.S. Provisional Patent Application Ser. No. 62/500,315, filed May 2, 2017, entitled “TORQUE LIMITER WEDGES,” the contents of which are incorporated herein by reference in their entirety.

### FIELD OF THE INVENTION

The present invention relates to wedges for retaining printed circuit boards within frames providing support and heat dissipation.

### SUMMARY OF THE INVENTION

The present invention relates to a wedge for retaining a printed circuit board (“PCB”) within a frame that provides support and heat dissipation for the printed circuit board. The wedge is movable between a relaxed condition, in which space is provided to insert a PCB into a slot within a frame, and an expanded condition, in which the wedge applies a lateral force so as to retain the PCB within the slot. In an embodiment, the wedge is moved between the relaxed position and the expanded position by applying a torque to a socket located at one end of the wedge. In an embodiment, the wedge is adapted to limit the applied torque, thereby limiting the lateral force applied by the wedge.

In an embodiment, a wedge includes a wedge body having a first end, a second end opposite the first end, an upper surface, and a lower surface opposite the upper surface. In an embodiment, a first slot extends from the upper surface toward but not through the lower surface proximate the first end. In an embodiment, a second slot extends from the upper surface toward but not through the lower surface proximate the second end. In an embodiment, an axial threaded hole extends from the second slot to the second end. In an embodiment, an end wedge is fixed to the wedge body at the first end. In an embodiment, a center wedge is slidably disposed on the wedge body intermediate the first and second ends. In an embodiment, a first side wedge is slidably disposed on the wedge body intermediate the first end and the center wedge and is positioned so as to overlap the first slot. In an embodiment, a second side wedge is slidably disposed on the wedge body intermediate the center wedge and the second end and is positioned so as to overlap the second slot. In an embodiment, the first side wedge is attached to the wedge body by a first extension spring having a first end fixed to the first side wedge and a second end fixed to the wedge body within the first slot. In an embodiment, the second side wedge is attached to the wedge body by a second extension spring having a first end fixed to the second side wedge and a second end fixed to the wedge body within the second slot. In an embodiment, a front wedge is slidably disposed on the wedge body at the second end and has an axial hole that is aligned with the axial threaded hole of the wedge body and an inwardly extending flange within the axial hole. In an embodiment, a head ratchet includes a threaded portion and an interface portion. In an embodiment, the threaded portion of the head ratchet engages the axial threaded hole of the wedge body. In an embodiment, the interface portion of the head ratchet is positioned within the axial hole of the front wedge.

In an embodiment, when the head ratchet is rotated in a first direction with respect to the wedge body, the threaded portion of the head ratchet moves axially with respect to the axial threaded hole of the wedge body in a direction toward the first end of the wedge body, thereby bearing on the flange of the front wedge and causing the front wedge to move toward the first end of the wedge body. In an embodiment, when the front wedge moves toward the first end of the wedge body, the shapes of the front wedge, the second side wedge, the center wedge, the first side wedge, and the end wedge cooperate to urge the first and second side wedges away from the lower surface of the wedge body. In an embodiment, a stud operator is positioned within the axial hole of the front wedge so as to abut the interface portion of the head ratchet. In an embodiment, rotation of the stud operator in the first direction causes corresponding rotation of the head ratchet in the first direction when an applied torque is less than a predetermined threshold torque. In an embodiment, rotation of the stud operator in the first direction does not cause corresponding rotation of the head ratchet in the first direction when the applied torque is greater than the predetermined threshold torque.

In an embodiment, the stud operator includes at least one ramped torque applying surface that is positioned so as to apply a torque to the head ratchet when the stud operator is rotated in the first direction. In an embodiment, the wedge includes a compression spring that cooperates with the stud operator to rotate the head ratchet in the first direction when the applied torque is less than the predetermined threshold torque. In an embodiment, the compression spring is adapted to allow the stud operator to disengage from the head ratchet when the applied torque is greater than the predetermined threshold torque.

In an embodiment, a wedge includes a wedge body having a first end, a second end opposite the first end, a middle portion. The middle portion includes a first horizontal wedge surface, a second horizontal wedge surface opposite the first horizontal wedge surface, and an axial hole extending from the first horizontal wedge surface to the second horizontal wedge surface. In an embodiment, a first horizontal wedge having a first end, a second end opposite the first end, a vertical wedge surface at the first end, a horizontal wedge surface at the second end, and a horizontal slot extending from the vertical wedge surface to the horizontal wedge surface is positioned adjacent the wedge body such that the horizontal wedge surface of the first horizontal wedge abuts the first horizontal wedge surface of the wedge body. In an embodiment, a first vertical wedge having a first end, a second end opposite the first end, a first vertical wedge surface at the first end, a second vertical wedge surface at the second end, and a vertical slot extending from the first vertical wedge surface to the second vertical wedge surface is positioned adjacent the wedge body and the first horizontal wedge such that the second vertical wedge surface of the first vertical wedge abuts the vertical wedge surface of the first horizontal wedge. In an embodiment, a front wedge having a first end, a second end opposite the first end, a vertical wedge surface at the second end, and an axial hole extending from the first end to the vertical wedge surface is positioned adjacent the wedge body and the first vertical wedge such that the vertical wedge surface of the front wedge abuts the first vertical wedge surface of the first vertical wedge and the front wedge is proximate to the first end of the wedge body. In an embodiment, the axial hole of the front wedge includes a first portion located proximate to the first end and having a first diameter, a second portion located proximate to the second end and having a second diameter that is less than the first diameter, and a flange between the first and second portions. In an embodiment, a second horizontal wedge having a first end, a second end opposite the first end, a horizontal wedge surface at the first end, a vertical wedge surface at the second end, and a horizontal slot extending from the horizontal wedge surface to the vertical wedge surface is positioned adjacent the wedge body such that the horizontal wedge surface of the first horizontal wedge abuts the second horizontal wedge surface of the wedge body. In an embodiment, a second vertical wedge having a first end, a second end opposite the first end, a first vertical wedge surface at the first end, a second vertical wedge surface at the second end, and a vertical slot extending from the first vertical wedge surface to the second vertical wedge surface is positioned adjacent the wedge body and the second horizontal wedge such that the first vertical wedge surface of the second vertical wedge abuts the vertical wedge surface of the second horizontal wedge. In an embodiment, an end wedge having a first end, a second end opposite the first end, a vertical wedge surface at the first end, and a threaded axial hole extending from the vertical wedge surface to the second end is positioned adjacent the wedge body and the second vertical wedge such that the vertical wedge surface of the end wedge abuts the second vertical wedge surface of the second vertical wedge and the end wedge is proximate to the second end of the wedge body.

In an embodiment, a head ratchet includes a first end, a second end opposite the first end, a second end opposite the first end, an interface portion proximate to the first end, and a threaded portion proximate to the second end. In an embodiment, the threaded portion of the head ratchet engages the threaded axial hole of the end wedge. In an embodiment, the interface portion of the head ratchet is positioned within the axial hole of the front wedge.

In an embodiment, when the head ratchet is rotated in a first direction with respect to the wedge body, the threaded portion of the head ratchet moves axially with respect to the threaded axial hole of the end wedge in a direction toward the second of the wedge body, thereby bearing on the flange of the front wedge and causing the front wedge to move toward the second end of the wedge body. In an embodiment, when the front wedge moves toward the second end of the wedge body, the shapes of the front wedge, the first vertical wedge, the first horizontal wedge, the middle portion of the wedge body, the second horizontal wedge, the second vertical wedge, and the end wedge cooperate to urge the first and second vertical wedges and the first and second horizontal wedges away from the wedge body. In an embodiment, a stud operator is positioned within the axial hole of the front wedge so as to abut the interface portion of the head ratchet. In an embodiment, rotation of the stud operator in the first direction causes corresponding rotation of the head ratchet in the first direction when an applied torque is less than a predetermined threshold torque. In an embodiment, rotation of the stud operator in the first direction does not cause corresponding rotation of the head ratchet in the first direction when the applied torque is greater than the predetermined threshold torque.

In an embodiment, the stud operator includes at least one ramped torque applying surface that is positioned so as to apply a torque to the head ratchet when the stud operator is rotated in the first direction. In an embodiment, the wedge includes a compression spring that cooperates with the stud operator to rotate the head ratchet in the first direction when the applied torque is less than the predetermined threshold torque. In an embodiment, the compression spring is adapted to allow the stud operator to disengage from the head ratchet when the applied torque is greater than the predetermined threshold torque.

In an embodiment, a device includes a body, a front wedge, a body wedge, a ratchet, and an internal thread, the body having a first end, a second end opposite the first end, a middle portion between the first and second ends, a longitudinal axis, and a hole extending axially through at least a portion of the body along the longitudinal axis thereof, the front wedge having a hole extending therethrough and a face, the front wedge being positioned at the first end of the body such that the hole of the front wedge is aligned with the hole of the body, the body wedge having a first face and a second face, the body wedge being positioned adjacent the front wedge and adjacent the body, the first face of the body wedge being flush with the face of the front wedge, wherein the first face of the body wedge and the face of the front wedge are configured such that motion of the front wedge toward the second end of the body causes motion of the body wedge away from the body in a first direction that is perpendicular to the longitudinal axis, the ratchet having an interface portion and a threaded portion, the ratchet being positioned within the hole of the body and within the hole of the front wedge, the ratchet and the hole of the front wedge being sized and shaped such that motion of the ratchet along the longitudinal axis of the body toward the second end of the body causes corresponding motion of the front wedge along the longitudinal axis of the body toward the second end of the body, the internal thread configured to receive threadedly the threaded portion of the ratchet, whereby rotation of the ratchet with respect to the body about the longitudinal axis in a first direction causes the ratchet to move toward the second end of the body, and whereby rotation of the ratchet with respect to the body about the longitudinal axis in a second direction opposite the first direction causes the ratchet to move away from the second end of the body.

In an embodiment, the device also includes a stud operator positioned within the hole of the front wedge and adjacent to the interface portion of the ratchet, wherein the stud operator and the ratchet are configured such that rotation of the stud operator with respect to the body about the longitudinal axis in the second direction drives corresponding rotation of the ratchet with respect to the body about the longitudinal axis in the second direction. In an embodiment, the ratchet includes at least one torque receiving surface, wherein the stud operator includes at least one torque applying surface, and wherein the at least one torque applying surface of the stud operator and the at least one torque receiving surface of the ratchet are oriented obliquely to one another. In an embodiment, the device also includes a front operator and a spring, the front operator positioned within the hole of the front wedge, the spring positioned within the hole of the front wedge and intermediate the front operator and the stud operator, the spring being configured to urge the stud operator toward the ratchet, wherein the spring, the at least one torque receiving surface of the ratchet, and the at least one torque applying surface of the stud operator cooperate to produce the threshold torque.

In an embodiment, the device also includes at least one attachment point configured for attaching the device to an underlying structure. In an embodiment, the face of the front wedge is a ramped face that is inclined with respect to the longitudinal axis of the body, wherein the first face of the body wedge is a ramped face that is inclined with respect to the longitudinal axis of the body, and wherein the second face of the body wedge is a ramped face that is inclined with respect to the longitudinal axis of the body.

In an embodiment, the stud operator and the ratchet are configured such that rotation of the stud operator with respect to the body about the longitudinal axis in the first direction with an applied torque that is less than a threshold torque drives corresponding rotation of the ratchet with respect to the body about the longitudinal axis in the first direction, and such that rotation of the stud operator with respect to the body about the longitudinal axis in the first direction with an applied torque that is greater than the threshold torque causes the stud operator to rotate with respect to the ratchet and does not cause corresponding rotation of the ratchet with respect to the body about the longitudinal axis in the first direction.

In an embodiment, the device also includes a middle wedge having a first face, a second face opposite the first face of the middle wedge, and a slot extending through the middle wedge from the first face of the middle wedge to the second face of the middle wedge, the slot being configured to receive the body therein, wherein the body is positioned within the slot of the middle wedge such that the middle wedge is aligned with the middle portion of the body and such that the first face of the middle wedge abuts the second face of the body wedge.

In an embodiment, the device is configured such that motion of the front wedge toward the second end of the body forces the front wedge against the body wedge and forces the body wedge against the middle wedge, whereby the front wedge and the middle wedge press against the body wedge from opposite sides, and whereby the pressure exerted on the body wedge by the front wedge, the pressure exerted on the body wedge by the middle wedge, engagement between the face of the front wedge and the first face of the body wedge, and engagement between the first face of the middle wedge and the second face of the body wedge cooperate to urge the body wedge away from the body in the first direction.

In an embodiment, the device also includes an end wedge and a second body wedge, the end wedge attached to the second end of the body, the end wedge including a face that is inclined with respect to the longitudinal axis of the body, the second body wedge having a first face, a second face opposite the first face of the second body wedge, and a slot extending through the second body wedge from the first face of the second body wedge to the second face of the second body wedge, the body being received within the slot of the second body wedge, the second body wedge being positioned adjacent the end wedge, the first face of the second body wedge being flush with the second face of the middle wedge, and the second face of the second body wedge being flush with the face of the end wedge, wherein the first face of the second body wedge, the second face of the second body wedge, the second face of the middle wedge, and the face of the end wedge are configured such motion of the middle wedge toward the second end of the body causes motion of the second body wedge away from the body in the first direction.

In an embodiment, the device also includes a spring positioned intermediate the body wedge and the body, the spring being configured so as to resist movement of the body wedge away from the body in the first direction. In an embodiment, the internal thread is formed within the hole of the body. In an embodiment, the face of the front wedge is a ramped face that is inclined with respect to the longitudinal axis of the body, wherein the first face of the body wedge is a ramped face that is inclined with respect to the longitudinal axis of the body, wherein the second face of the body wedge is a ramped face that is inclined with respect to the longitudinal axis of the body, wherein the first face of the middle wedge is a ramped face that is inclined with respect to the longitudinal axis of the body, and wherein the second face of the middle wedge is a ramped face that is inclined with respect to the longitudinal axis of the body.

In an embodiment, the device also includes a side wedge a having a first face, a second face opposite the first face of the side wedge, and a passage extending through the side wedge from the first face of the side wedge to the second face of the side wedge, the side wedge being positioned adjacent the body wedge and adjacent the body such that the first face of the side wedge is flush with the second face of the body wedge, wherein the middle portion of the body has a first face facing generally toward the first end of the body and a second face opposite the first face of the middle portion of the body and facing generally toward the second end of the body. In an embodiment, the second face of the body wedge, the first face of the middle portion of the body, the first face of the side wedge, and the second face of the side wedge are configured such that when the side wedge is positioned adjacent the body wedge and adjacent the body, motion of the front wedge toward the second end of the body causes motion of the side wedge away from the body in a second direction that is perpendicular to the longitudinal axis and perpendicular to the first direction.

In an embodiment, the device also includes an end wedge, a second body wedge, and a second side wedge, the end wedge having a hole extending therethrough and a face, wherein the internal thread is formed within the hole of the end wedge, the second body wedge having a first face, a second face opposite the first face of the second body wedge, and a hole extending through the second body wedge from the first face of the second body wedge to the second face of the second body wedge, the second side wedge having a first face, a second face opposite the first face of the second side wedge, and a hole extending through the second side wedge from the first face of the second side wedge to the second face of the second side wedge, wherein the second side wedge is positioned adjacent the body such that the first face of the second side wedge is flush with the second face of the middle portion of the body and such that the hole of the second side wedge is aligned with the longitudinal axis of the body, wherein the second body wedge is positioned adjacent the body such that the first face of the second body wedge is flush with the second face of the second side wedge and such that the hole of the second body wedge is aligned with the longitudinal axis of the body, and wherein the end wedge is positioned adjacent the body such that the face of the end wedge is flush with the second face of the second body wedge and such that the hole of the end wedge is aligned with the longitudinal axis of the body.

In an embodiment, the second face of the middle portion of the body, the first face of the second side wedge, the second face of the second side wedge, and the first face of the second body wedge are configured such that motion of the end wedge toward the first end of the body causes motion of the second side wedge away from the body in the second direction, wherein the second face of the second side wedge, the first face of the second body wedge, the second face of the second body wedge, and the face of end wedge are configured such that motion of the end wedge toward the first end of the body causes motion of the second body wedge away from the body in the first direction.

In an embodiment, the threads of the ratchet engage threadedly the internal thread of the hole of the end wedge, whereby advancement of the ratchet causes motion of the front wedge toward the second end of the body and causes motion of the end wedge toward the first end of the body. In an embodiment, the device also includes a spring positioned intermediate the body and the side wedge and configured so as to resist movement of the side wedge away from the body in the second direction. In an embodiment, the face of the front wedge is a ramped face that is inclined with respect to the longitudinal axis of the body, wherein the first face of the body wedge is a ramped face that is inclined with respect to the longitudinal axis of the body, wherein the second face of the body wedge is a ramped face that is inclined with respect to the longitudinal axis of the body, wherein the first face of the side wedge is a ramped face that is inclined with respect to the longitudinal axis of the body, wherein the second face of the side wedge is a ramped face that is inclined with respect to the longitudinal axis of the body, wherein the first face of the middle portion of the body is a ramped face that is inclined with respect to the longitudinal axis of the body, and wherein the second face of the middle portion of the body is a ramped face that is inclined with respect to the longitudinal axis of the body.

### BRIEF DESCRIPTION OF THE DRAWINGS

FIG. 1 is a top perspective view of a first embodiment of a wedge;

FIG. 2 is a bottom perspective view of the wedge shown in FIG. 1;

FIG. 3 is a bottom perspective view of the wedge shown in FIG. 1, the wedge being shown in an expanded condition;

FIG. 4 is an exploded view of the wedge shown in FIG. 1, with certain elements of the wedge shown in a transparent manner in order to illustrate internal portions thereof;

FIG. 5 is a top, cross-sectional view of the wedge shown in FIG. 1;

FIG. 6 is a front, cross-sectional view of the wedge shown in FIG. 1;

FIG. 7 is a front, cross-sectional view of the wedge shown in FIGS. 1 and 6, the wedge being shown in the expanded condition;

FIG. 8 is a top perspective view of a second embodiment of a wedge;

FIG. 9 is a bottom perspective view of the wedge shown in FIG. 8;

FIG. 10 is a top perspective view of the wedge shown in FIG. 1, the wedge being shown in an expanded condition;

FIG. 11 is an exploded view of the wedge shown in FIG. 8, with certain elements of the wedge shown in a transparent manner in order to illustrate internal portions thereof;

FIG. 12 is an enlarged view of a portion of the exploded view of FIG. 11;

FIG. 13 is a top cross-sectional view of the wedge shown in FIG. 8, the wedge being shown in a relaxed condition;

FIG. 14 is a side cross-sectional view of the wedge shown in FIG. 8, the wedge being shown in a relaxed condition;

FIG. 15 is a top partial cross-sectional view of the wedge shown in FIG. 8, the wedge being shown in an expanded condition; and

FIG. 16 is a side partial cross-sectional view of the wedge shown in FIG. 8, the wedge being shown in an expanded condition.

### DETAILED DESCRIPTION OF THE DRAWINGS

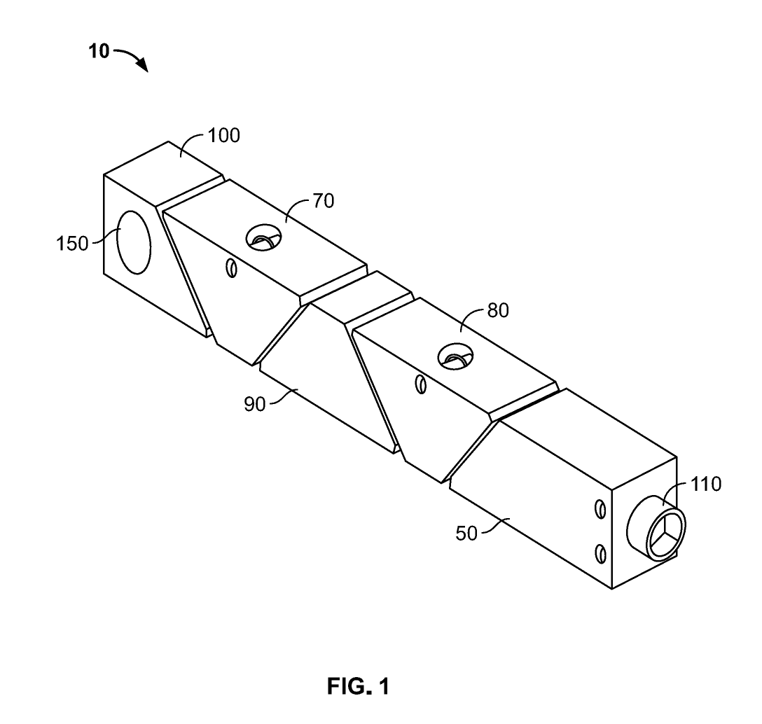

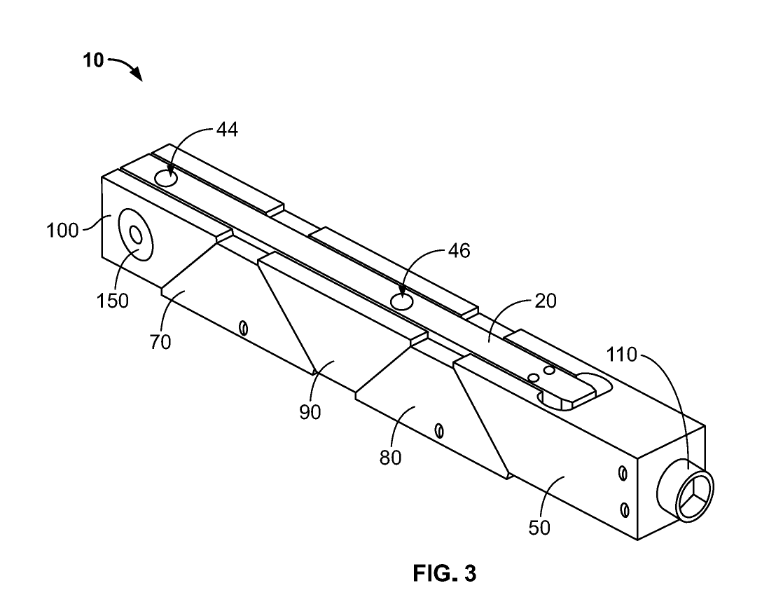

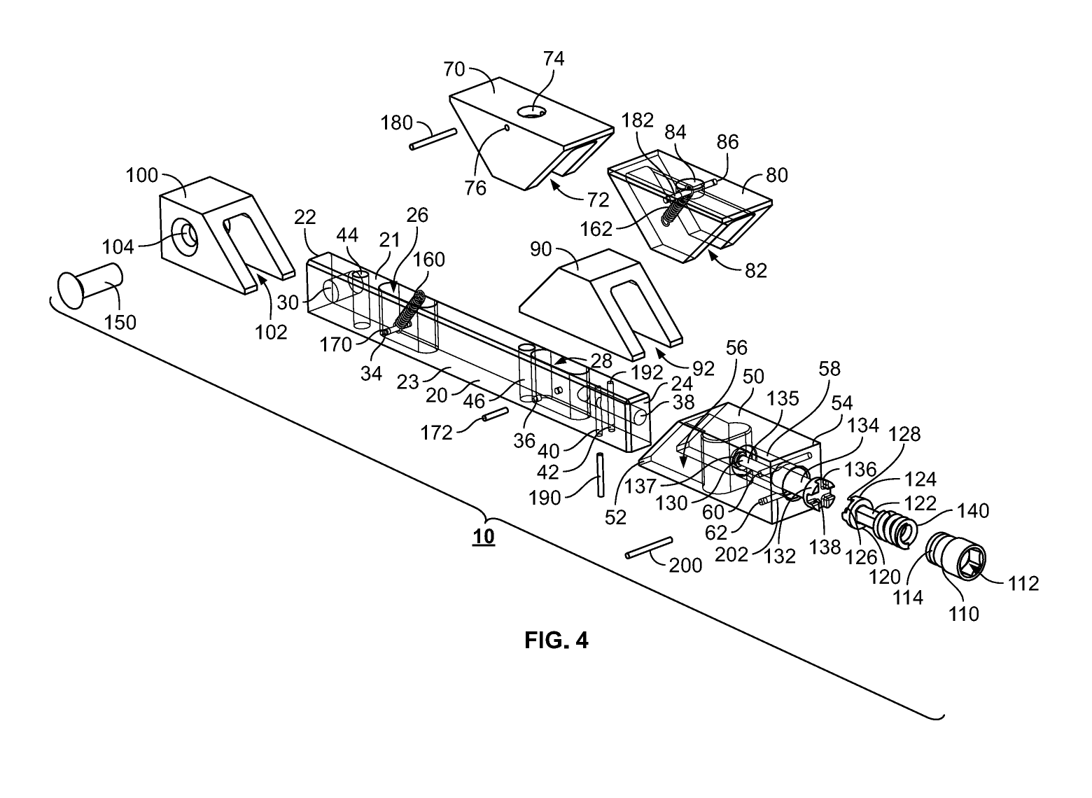

Referring to FIGS. 1 through 4, in a first embodiment, a wedge 10 includes a wedge body 20. The wedge body 20 has first and second ends 22, 24, an upper surface 21, and a lower surface 23. First and second slots 26, 28 extend from the upper surface 21 of the wedge body 20 and to, but not through, the lower surface 23 of the wedge body 20. The first and second slots 26, 28 are positioned proximate the first and second ends 22, 24, respectively. A transverse rivet hole 30 extends through the wedge body 20 intermediate the first slot 26 and the first end 22. First and second transverse wire holes 34, 36 extend through the wedge body 20 within the first and second slots 26, 28, respectively. An axial hole 38 extends from the second slot 28 to the second end 24 and intermediate the upper and lower surfaces 21, 23. The axial hole 38 includes internal threads. First and second vertical wire holes 40, 42 extend through the wedge body 20 from the upper surface 21 to the lower surface 23 and to opposite sides of the axial hole 38, and are positioned such that they partially pass within the axial hole 38. First and second threaded mounting holes 44, 46 (see FIGS. 3 and 4) are formed within the wedge body 20 as attachment points for attaching the wedge 10 to an underlying structure, such as a frame.

Continuing to refer to FIGS. 1 through 4, in an embodiment, the wedge 10 includes a front wedge 50 having a first end 52 and a second end 54. A slot 56 is formed within the first end 52 of the front wedge 50 and is sized and shaped to receive the second end 24 of the wedge body 20. An axial hole 58 extends through the front wedge 50 from the slot 56 to the second end 54. First and second transverse wire holes 60, 62 extend across the front wedge 50, and are positioned such that they partially overlap the axial hole 58. A flange 64 (see FIG. 6) extends partially across the axial hole 58 at its intersection with the slot 56, thereby providing a narrowed portion of the axial hole 58 capable of bearing an axial load on the front wedge 50.

Continuing to refer to FIGS. 1 through 4, in an embodiment, the wedge 10 includes first and second side wedges 70, 80. Slots 72, 82 are formed within the first and second side wedges 70, 80, respectively, and are sized and shaped so as to receive the wedge body 20. Vertical holes 74, 84 extend through the first and second side wedges 70, 80, respectively. Transverse wire holes 76, 86 extend through the first and second side wedges 70, 80, respectively. The transverse wire holes 76, 86 are positioned so as to intersect the vertical holes 74, 84, respectively.

Referring to FIG. 4, in an embodiment, the wedge 10 includes a center wedge 90. The center wedge 90 includes a slot 92 that is sized and shaped so as to receive the wedge body 20.

Continuing to refer to FIGS. 1 through 4, in an embodiment, the wedge 10 includes an end wedge 100. The end wedge includes a slot 102 that is sized and shaped so as to receive the first end 22 of the wedge body 20. The end wedge 100 also includes a transverse rivet hole 104 that is positioned such that, when the slot 102 of the end wedge 100 receives the first end 22 of the wedge body 20, the transverse rivet hole 104 of the end wedge 100 is aligned with the transverse rivet hole 30 of the wedge body 20.

Continuing to refer to FIGS. 1 through 4, in an embodiment, the wedge 10 includes a front operator 110 that is sized and shaped so as to be received within the axial hole 58 of the front wedge 50. A through slot 112 extends through the front operator 110. In an embodiment, the through slot 112 has a hexagonal cross-section. A groove 114 extends around the front operator 110.

Continuing to refer to FIGS. 1 through 4, in an embodiment, the wedge 10 includes a stud operator 120. The stud operator 120 includes an operator torque portion 122 that is sized and shaped so as to be received within the through slot 112 of the front operator 110 in a manner such that the stud operator 120 may move axially with respect to the front operator 110 but may not rotate with respect to the front operator 110. The stud operator 120 also includes a ratchet torque portion 124 that is positioned opposite the operator torque portion 122. The ratchet torque portion 124 includes a plurality of ramped torque applying surfaces 126 that are positioned and oriented so as to apply torque when the stud operator 120 is rotated in a first direction. The ratchet torque portion 124 also includes a plurality of flat torque applying surfaces 128 that are positioned and oriented so as to apply torque when the stud operator 120 is rotated in a second direction that is opposite the first direction. In an embodiment, the ratchet torque portion 124 includes four of the ramped torque applying surfaces 126 and four of the flat torque applying surfaces 128.

Continuing to refer to FIGS. 1 through 4, in an embodiment, the wedge 10 includes a head ratchet 130. The head ratchet 130 includes an interface portion 132 that is sized and shaped so as to engage the ratchet torque portion 124 of the stud operator 120 such that, when these elements engage one another, rotation of the stud operator 120 causes corresponding rotation of the head ratchet 130. The head ratchet 130 also includes a threaded portion 134 adjacent the interface portion 132. The threaded portion 134 is sized and shaped so as to threadedly engage the internal threads of the axial hole 30 of the wedge body 10. The head ratchet 130 also includes a groove portion 135 adjacent the threaded portion 134 and opposite the interface portion 132. The groove portion 135 has a diameter that is less than that of the threaded portion 134. The head ratchet 130 also includes a head 137 adjacent the groove portion 135 and opposite the threaded portion 134. The head 137 has a diameter that is greater than that of the groove portion 135. The interface portion 132 includes a first plurality of flat torque receiving surfaces 136 that are positioned and oriented so as to receive a torque applied in a first direction. The interface portion 132 also includes a second plurality of flat torque receiving surfaces 138 that are positioned and oriented so as to receive a torque applied in a second direction. In an embodiment, the interface portion 132 includes four of the flat torque receiving surfaces 136 and four of the flat torque receiving surfaces 138.

Continuing to refer to FIGS. 1 through 4, in an embodiment, the wedge 10 includes a compression spring 140. The compression spring 140 is sized and shaped so as to be placed over the operator torque portion 122 of the stud operator 120.

Continuing to refer to FIGS. 1 through 4, in an embodiment, the wedge 10 includes a rivet 150. The rivet 150 is sized and shaped so as to be received within the transverse rivet holes 30 and 104 of the wedge body 20 and the end wedge 100, respectively.

Continuing to refer to FIGS. 1 through 4, in an embodiment, the wedge 10 includes first and second extension springs 160, 162. The first and second extension springs 160, 162 are sized and shaped so as to be received within the first and second slots 26, 28, respectively, of the wedge body 20. As will be described in greater detail hereinafter, when the wedge 10 is assembled, each of the first and second extension springs 160, 162 is fastened so as to connect a corresponding one of the first and second side wedges 70, 80 to the wedge body 20. In the exploded view of FIG. 4, the first second extension spring 160 is shown fastened to the wedge body 20 but not fastened to the first side wedge 70, while the second extension spring 162 is shown fastened to the second side wedge 80 but not fastened to the wedge body 20.

Continuing to refer to FIGS. 1 through 4, in an embodiment, the wedge 10 includes wires 170, 172, 180, 182, 190, 192, 200, 202 (collectively “the wires”). The wires are sized and shaped so as to retain the various elements of the wedge 10 in operational relationship to one another as will be described hereinafter. As will be described in greater detail hereinafter, when the wedge 10 is assembled, each of the wires 170, 172, 180, 182, 190, 192, 200, 202 is positioned within a corresponding hole of one of the other elements of the wedge 10. In the exploded view of FIG. 4, some of the wires are shown in their assembled positions (i.e., the wire 170 is shown positioned within the transverse wire hole 34 of the wedge body 20; the wire 182 is shown positioned within the transverse wire hole 86 of the second side wedge 80; the wire 192 is shown positioned within the second vertical wire hole 42 of the wedge body 20; the wire 202 is shown positioned within the second transverse wire hole 62 of the front wedge 50). In the exploded view of FIG. 4, some of the wires (i.e., the wires 172, 180, 190, 200) are shown disassembled from other elements of the wedge 10. As used herein, the term “wires” refers to rigid elements capable of providing structural stability to the wedge 10.

Continuing to refer to FIGS. 1 through 4, assembly of the wedge 10 is described. The end wedge 100 is secured to the first end 22 of the wedge body 20 by the installing the rivet 150 within the transverse rivet holes 30 and 104 of the wedge body 20 and the end wedge 100, respectively. The center wedge 90 is placed over the wedge body 20 intermediate the first and second ends 22, 24 thereof, such that the wedge body 20 is received within the slot 92 of the center wedge 90.

Continuing to refer to FIGS. 1 through 4, the first extension spring 160 is placed within the first slot 26 of the wedge body 20. The first extension spring 160 is then secured in this position by passing the wire 170 through the transverse wire hole 34 of the wedge body 20 and one end of the first extension spring 160 and securing the wire 170 in place. The first side wedge 70 is placed over the first slot 26 of the wedge body 20 such that the wedge body 20 is received within the slot 72 of the first side wedge 70. The first side wedge 70 is then secured in this position by extending the first extension spring 160, passing the wire 180 through the transverse wire hole 76 of the first side wedge 70 and an opposite end of the first extension spring 160, and securing the wire 180 in place. The vertical hole 74 may provide access to the first extension spring 160 within the first slot 26 of the wedge body 20 during this process. Once the first side wedge 70 has been secured in this manner, motion of the first side wedge 70 away from the wedge body 20 will be opposed by the action of the first extension spring 160. The second extension spring 162 and second side wedge 80 are then secured to the second slot 28 of the wedge body 20 by repeating the same steps described above. Once the first and second side wedges 70, 80 have been secured in the above manner, motion of the center wedge 40 is restrained by the first and second side wedges 70, 80, and, more particularly, by the operation of the first and second extension springs 160, 162 to restrict motion of the first and second side wedges 70, 80, respectively.

Continuing to refer to FIGS. 1 through 4, the first and second wires 190, 192 are positioned within the first and second vertical wire holes 40, 42 of the wedge body 20, and are secured therein. The front wedge 50 is positioned adjacent the wedge body 20 such that the second end 24 of the wedge body 20 is within the slot 56 of the front wedge 50, and such that the front wedge 50 abuts the second side wedge 80. The head ratchet 130 is placed within the axial hole 58 of the front wedge 50 such that the interface portion 132 of the head ratchet 130 abuts the flange 64 of the front wedge 50, and such that the threaded portion 134 extends through the flange 64 of the front wedge 50 to threadedly engage the internal threads of the axial hole 38 of the wedge body 20. The first and second wires 190, 192 pass within the axial hole 38 of the wedge body 20, which intersects the first and second vertical wire holes 40, 42 of the wedge body 20, and therefore limit the axial travel of the head ratchet 130 within the axial hole 38 of the wedge body 20.

Continuing to refer to FIGS. 1 through 4, the stud operator 120 is positioned within the axial hole 58 of the front wedge 50 such that the ratchet torque portion 124 of the stud operator 120 abuts the interface portion 132 of the head ratchet 130. The compression spring 140 is positioned within the axial hole 58 of the front wedge 50 such that it surrounds the operator torque portion 122 of the stud operator 120. The front operator 110 is positioned within the axial hole 58 of the front wedge 50 such that the operator torque portion 122 of the stud operator 120 is within the through slot 112 of the front operator 110. Therefore, the stud operator 120 and the front operator 110 can move axially with respect to one another, but cannot rotate with respect to one another. The front operator 110 is secured in such position by placing the wires 200, 202 through the first and second transverse wire holes 60, 62 of the front wedge 50 and through the groove 114 of the front operator 110, and securing the wires 200, 202 in such position. The wires 200, 202 therefore prevent the front operator 110, the compression spring 140, the stud operator 120, and the head ratchet 130 from being removed from the axial hole 58 of the front wedge 50. When the above-mentioned elements are so positioned, the compression spring 140 is compressed between the front operator 110 and the stud operator 120. Therefore, the compression spring 140 urges the stud operator 120 in a direction away from the front operator 110 and toward the head ratchet 130, thereby urging the stud operator 120 toward a position such that the ratchet torque portion 124 of the stud operator 120 abuts the interface portion 132 of the head ratchet 130.

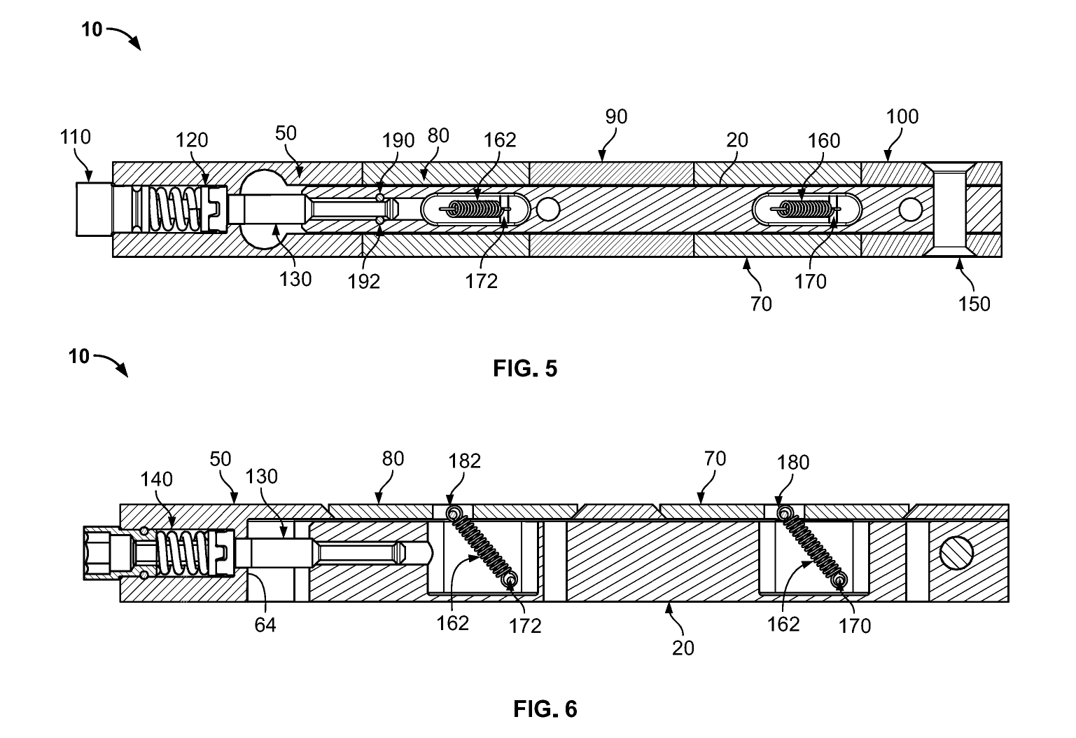

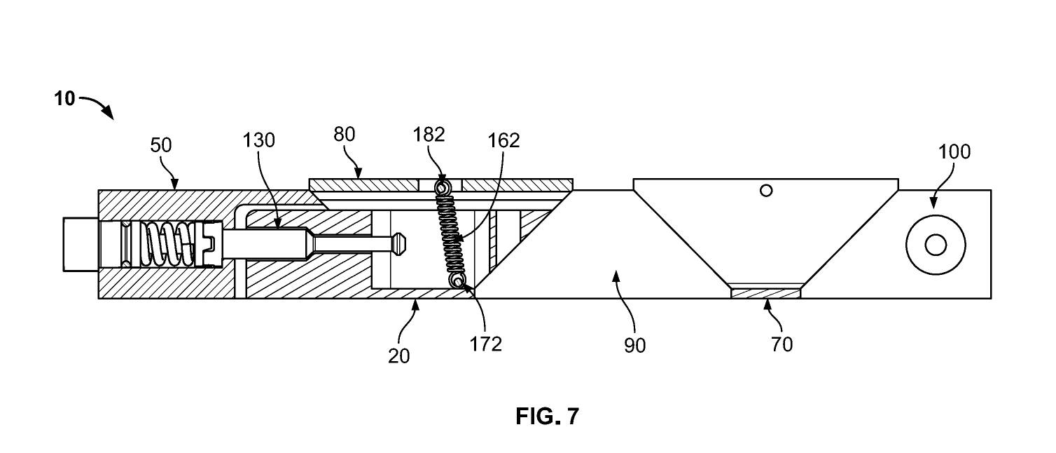

Referring now to FIGS. 1 through 7, operation of the wedge 10 in an expanding direction is described. A user inserts an appropriate tool into the slot 112 of the front operator 110. For example, in an embodiment in which the slot 112 is hexagonal, a hex key may be an appropriate tool. The user rotates the tool in a clockwise direction within the slot 112, thereby rotating the front operator 110. As described above, the operator torque portion 122 of the stud operator 120 is received within the slot 112 of the front operator 110. Therefore, rotation of the front operator 110 causes corresponding rotation of the stud operator 120. The clockwise rotation of the front operator 110 and the stud operator 120 corresponds to the first direction of torque described above with reference to the stud operator 120 and the head ratchet 130. Therefore, clockwise rotation of the stud operator 120 drives the ramped torque applying surfaces 126 of the stud operator 120 against the flat torque receiving surfaces 136 of the head ratchet 130, causing commensurate clockwise rotation of the head ratchet 130. Such rotation of the head ratchet 130 causes the head ratchet 130 to move within the axial slot 38 of the wedge body 20 in a direction toward the end wedge 100 due to the threaded engagement of the threaded portion 134 of the head ratchet 130 with the internal threads of the axial slot 38 of the wedge body 20. Because the interface portion 132 of the head ratchet 130 abuts the flange 64 of the front wedge 50, the axial motion of the head ratchet 130 drives corresponding axial motion of the front wedge 50 along the body wedge 20 in a direction toward the end wedge 100. Thus, the front wedge 50, the second side wedge 80, the center wedge 40, the first side wedge 70, and the end wedge 100 are forced together axially along the body wedge 20. Due to the wedge-like shapes of the front wedge 50, the second side wedge 80, the center wedge 40, the first side wedge 70, and the end wedge 100, such compression urges the first and second side wedges 70, 80 away from the body wedge 20 in a lateral direction, in opposition to the action of the first and second extension springs 160, 162, respectively, such that they move toward the expanded position shown in FIGS. 3 and 7. Once a predefined maximum torque has been reached, the ramped torque applying surfaces 126 of the stud operator 120 will disengage from the flat torque receiving surfaces 136 of the head ratchet 130, rather than applying further torque thereto. As a result, the stud operator 120 disengages from the head ratchet 130, and further advancement of the head ratchet 130 is prevented.

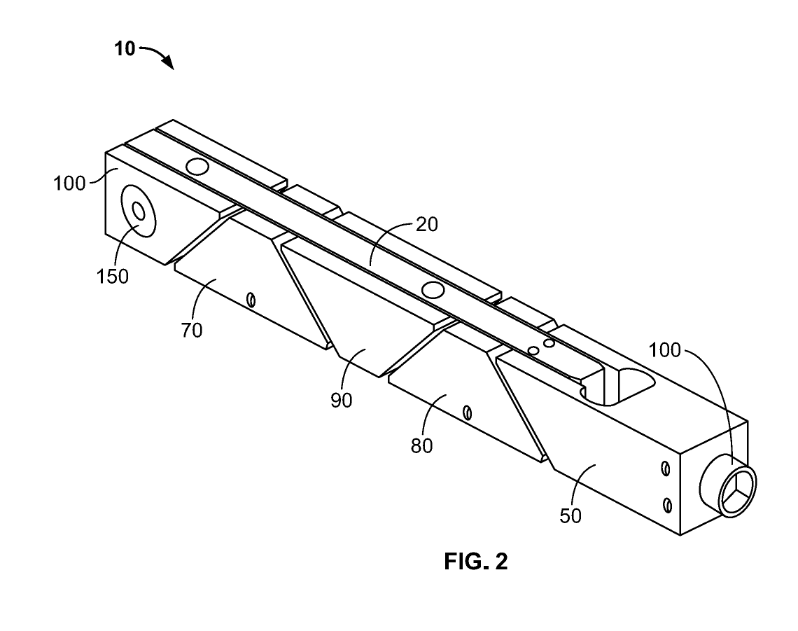

Continuing to refer to FIGS. 1 through 7, operation of the wedge 10 in a relaxing direction is described. A user inserts an appropriate tool into the slot 112 of the front operator 110. For example, in an embodiment in which the slot 112 is hexagonal, a hex key may be an appropriate tool. The user rotates the tool in a counterclockwise direction within the slot 112, thereby rotating the front operator 110. As described above, the front operator 110 and the stud operator 120 rotate together. The counterclockwise rotation of the front operator 110 and the stud operator 120 corresponds to the second direction of torque described above with reference to the stud operator 120 and the head ratchet 130. Therefore, counterclockwise rotation of the stud operator 120 drives the flat torque applying surfaces 128 of the stud operator 120 against the flat torque receiving surfaces 138 of the head ratchet 130, causing commensurate counterclockwise rotation of the head ratchet 130. Such rotation of the head ratchet 130 causes the head ratchet 130 to move axially with respect to the wedge body 20 in a directly away from the end wedge 100 due to the threaded engagement of the threaded portion 134 of the head ratchet 130 with the internal threads of the axial hole 38 of the body wedge 20. The first and second extension springs 160, 162 urge the first and second side wedges 70, 80, respectively, toward the wedge body 20 in the lateral direction. Due to such urging, the front wedge 50, the second side wedge 80, the center wedge 40, the first side wedge 70, and the end wedge 100 spread apart along the wedge body 20 once the axial force upon the front wedge 50 by the head ratchet 130 is relieved. Torquing may continue in this manner until the threaded portion 134 of the head ratchet 130 is disengaged from the threaded hole 38 of the wedge body 20. After such disengagement, the groove portion 135 of the head ratchet 130 floats within the threaded hole 38 of the wedge body 20, but the head ratchet 130 is prevented from being removed from the wedge body 20 by the head 137 of the head ratchet 130, which cannot be withdrawn past the wires 190, 192. At this point, the wedge 10 is in its relaxed position, as shown in FIGS. 1 and 2.

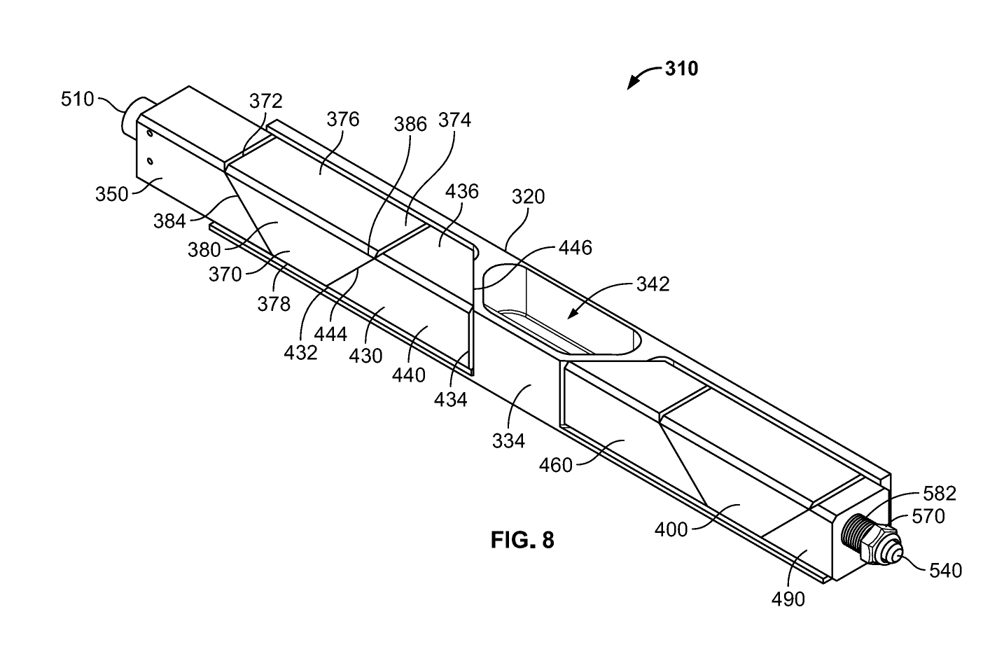

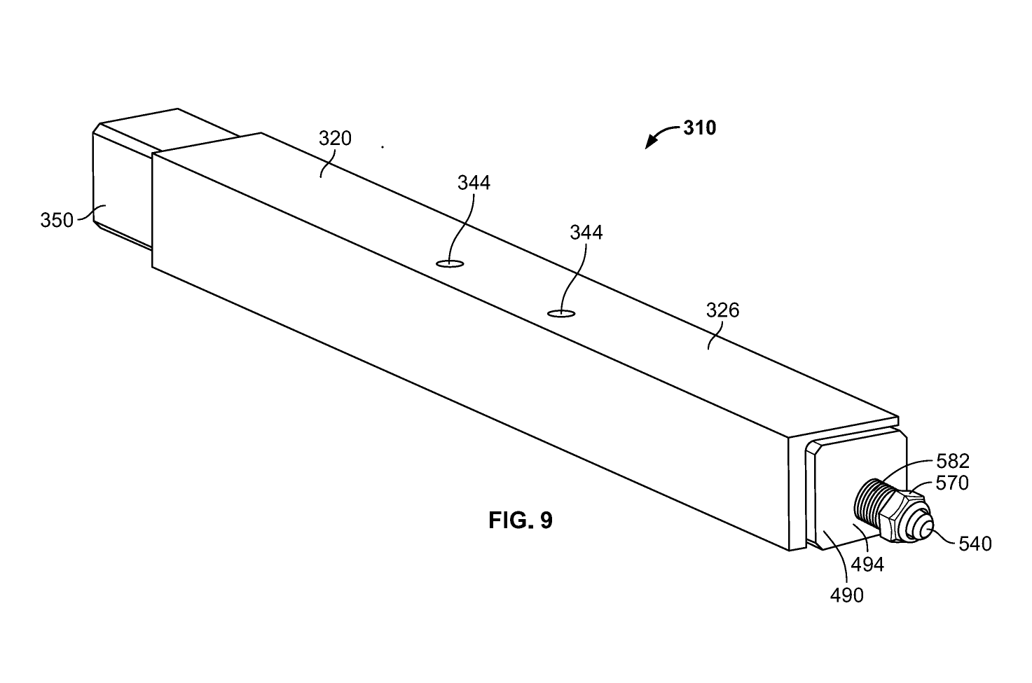

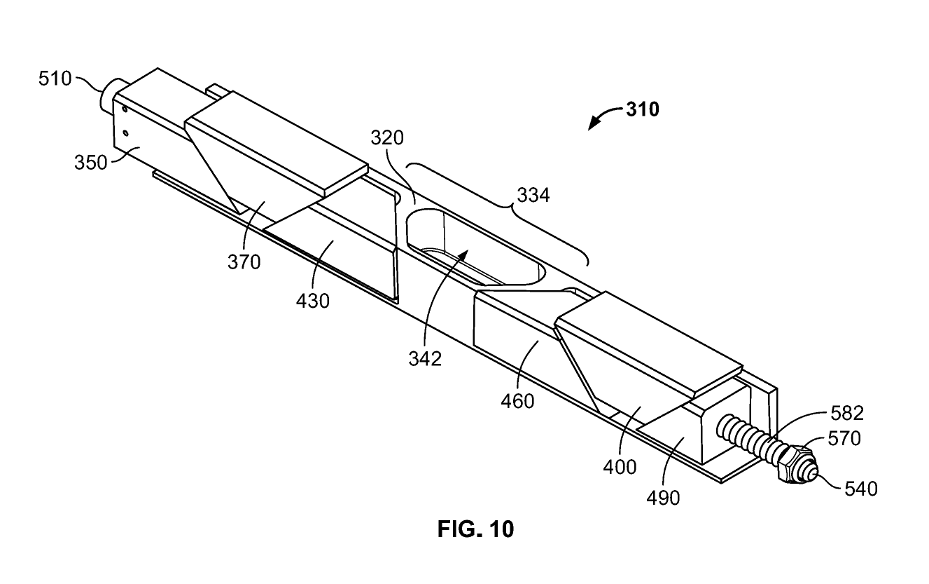

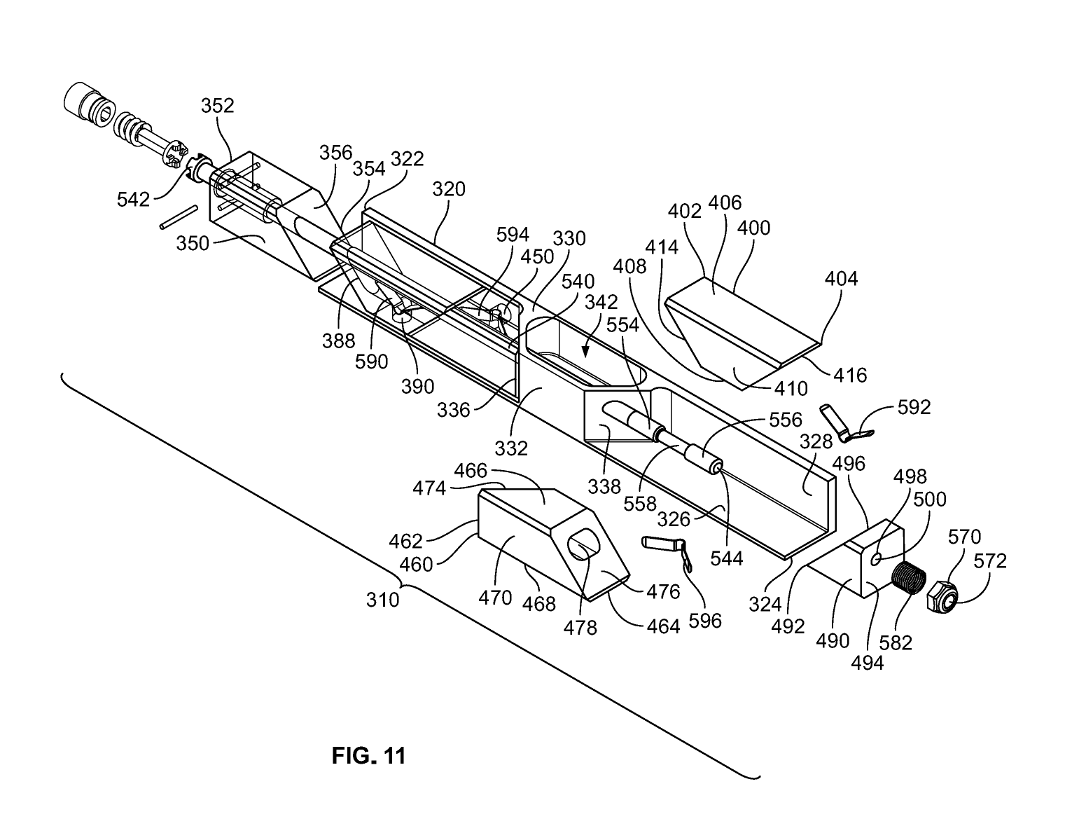

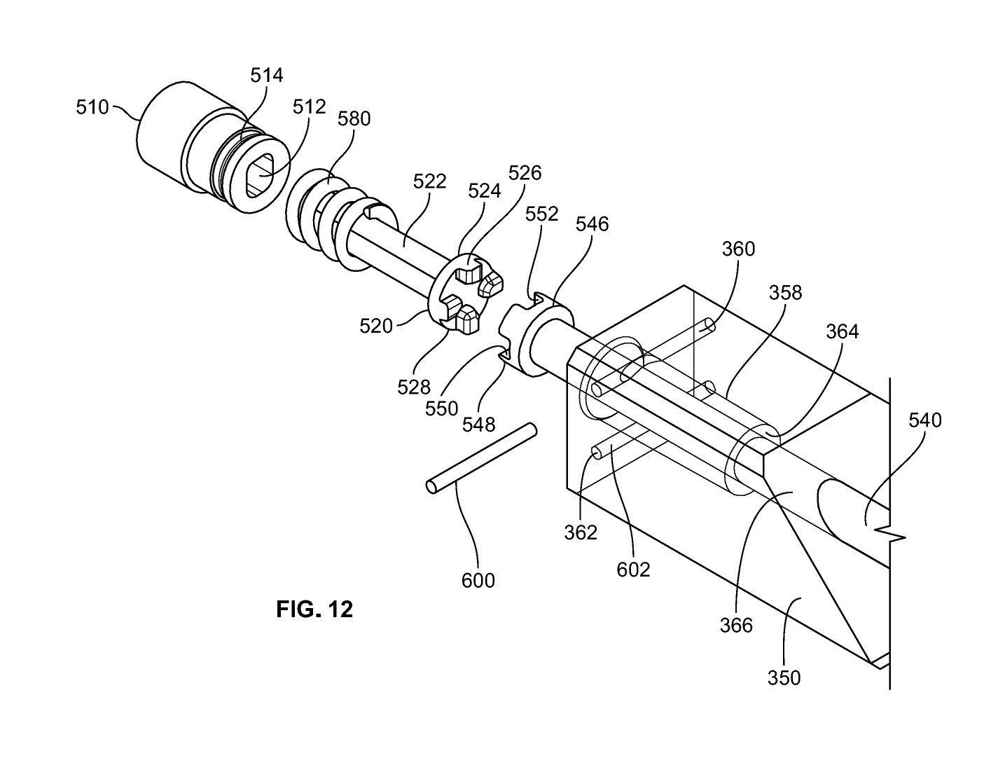

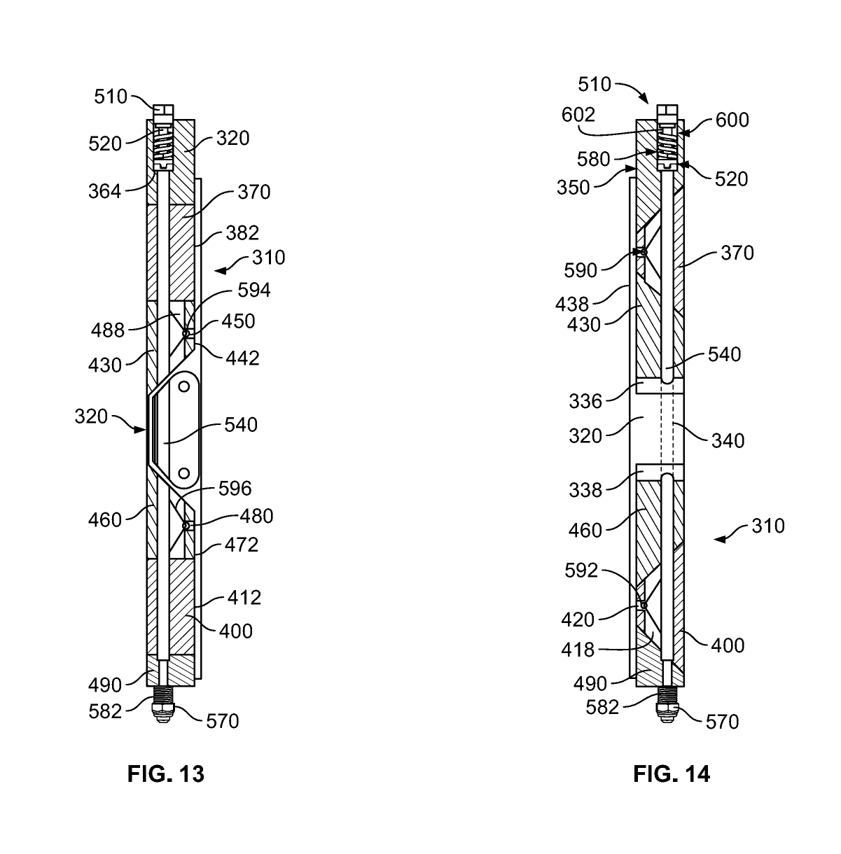

Referring to FIGS. 8 through 12, in a second embodiment, a wedge 310 includes a wedge body 320. The wedge body 320 has a first end 322 and a second end 324 opposite the first end 322 (see FIG. 11). The wedge body 320 has a generally L-shaped cross-section formed by a bottom wall 326 and a first side wall 328 (see FIG. 11). The wedge body 320 has a middle portion 334 (see FIG. 10) intermediate the first and second ends 322, 324, at which point the wedge body 320 has a generally rectangular cross-section including the bottom wall 326, the first side wall 328, a top wall 330 opposite the bottom wall 326, and a second side wall 332 opposite the first side wall 328 (see FIG. 11). The middle portion 326 has a first horizontal wedge surface 336 facing towards the first end 322 and extending diagonally from the first side wall 328 to the second side wall 332 and a second horizontal wedge surface 338 facing towards the second end 324 and extending diagonally from the first side wall 328 to the second side wall 332. The first side wall 328, the second side wall 332, the first horizontal wedge surface 336, and the second horizontal wedge surface 338 are oriented such that, when the wedge 310 is viewed from a perspective looking directly at the top wall 330 of the wedge body 320 (i.e., from the perspective shown in FIG. 13), the middle portion 334 has a generally trapezoidal profile. An axial hole 340 extends through the middle portion 334 from the first horizontal wedge surface 336 to the second horizontal wedge surface 338 (see FIG. 14). A groove 342 extends through the middle portion 334 from the top wall 330 to, but not through, the bottom wall 326. At least one mounting hole 344 (see FIG. 9) extends transversely from the groove 342 through the bottom wall 326. In an embodiment, the at least one mounting hole 344 is not centered between the first side wall 328 and the second side wall 332. In an embodiment, the mounting holes 344 are spaced apart from one another. In an embodiment, the at least one mounting hole 344 includes two of the mounting holes 344 extending transversely from the groove 342 through the bottom wall 326. In an embodiment, the at least one mounting hole 344 is provided in the wedge body 320 as an attachment point for attaching the wedge 310 to an underlying structure, such as a frame.

As used herein with reference to the wedge 310, “vertical” refers to a direction along an axis extending through and perpendicular to the bottom wall 326 and the top wall 330 of the wedge body 320. As used herein, “horizontal” refers to a direction along an axis extending through and perpendicular to the first side wall 328 and the second side wall 332, and perpendicular to the vertical axis noted above. As used herein, “longitudinal” and “axial” refer to a direction extending along an axis extending along and parallel to the axial hole 340, and perpendicular to the vertical and horizontal axes noted above. It will be apparent to those of skill in the art that the axes noted above are imaginary features described for reference purposes, and are not physical elements of the wedge 310. It will further be apparent to those of skill in the art that the terms “vertical,” “horizontal,” “longitudinal,” and “axial” are merely reference points for the wedge 310 itself, and are not meant to connote any particular orientation or alignment with respect to a frame in which the wedge 310 is installed, or to the surroundings of the wedge 310 more broadly.

Continuing to refer to FIGS. 8 through 12, in an embodiment, the wedge 310 includes a front wedge 350 having a first end 352 and a second end 354 opposite the first end 352 (see FIG. 11). The front wedge 350 includes a vertical wedge surface 356 at the second end 354. The front wedge 350 includes an axial hole 358 extending therethrough from the first end 352 to the vertical wedge surface 356 (see FIG. 12). First and second transverse wire holes 360, 362 extend across the front wedge 350, and are positioned and spaced apart from one another such that they partially overlap the axial hole 358 (see FIG. 12). A flange 364 (see FIG. 13) extends partially across the axial hole 358 intermediate the first and second ends 352, 354 of the front wedge 350, thereby providing a narrowed portion 366 of the axial hole 358. The flange 364 is capable of bearing an axial load on the front wedge 350.

Continuing to refer to FIGS. 8 through 12, in an embodiment, the wedge 310 includes a first vertical wedge 370 having a first end 372, a second end 374 opposite the first end 372, a top surface 376, a bottom surface 378 opposite the top surface 374, a first side surface 380, and a second side surface 382 (see FIG. 13) opposite the first side surface 380. The first vertical wedge 370 includes a first vertical wedge surface 384 at its first end 372 and a second vertical wedge surface 386 at its second end 374 (see FIG. 8). The top surface 376, the bottom surface 378, the first vertical wedge surface 384, and the second vertical wedge surface 386 of the first vertical wedge 370 are oriented such that, when viewed from a perspective looking directly at the second wall 332 of the wedge body 320 (i.e., from the perspective shown in FIG. 14), the first vertical wedge 370 has a generally trapezoidal profile. A vertical slot 388 extends through the first vertical wedge 370 from the first end 372 to the second end 374. The vertical slot 388 of the first vertical wedge 370 is vertically oblong. A hole 390 extends from the vertical slot 388 of the first vertical wedge 370 to the bottom surface 378 of the first vertical wedge 370 (see FIG. 11).

Continuing to refer to FIGS. 8 through 12, in an embodiment, the wedge 310 includes a second vertical wedge 400 having a first end 402, a second end 404 opposite the first end 402, a top surface 406, a bottom surface 408 opposite the top surface 404, a first side surface 410, and a second side surface 412 (see FIG. 13) opposite the first side surface 410. The second vertical wedge 400 includes a first vertical wedge surface 414 at the first end 402 and a second vertical wedge surface 416 at the second end 404. The top surface 406, the bottom surface 408, the first vertical wedge surface 414, and the second vertical wedge surface 416 of the second vertical wedge 400 are oriented such that, when viewed from a perspective looking directly at the second wall 332 of the wedge body 320 (i.e., from the perspective shown in FIG. 14), the second vertical wedge 400 has a generally trapezoidal profile. A vertical slot 418 (see FIG. 14) extends through the second vertical wedge 400 from the first end 402 to the second end 404. The vertical slot 418 of the second vertical wedge 400 is vertically oblong. A hole 420 (see FIG. 14) extends from the vertical slot 418 of the second vertical wedge 400 to the bottom surface 408 of the second vertical wedge 400.

Continuing to refer to FIGS. 8 through 12, in an embodiment, the wedge 310 includes a first horizontal wedge 430 having a first end 432, a second end 434 opposite the first end 432, a top surface 436, a bottom surface 438 (see FIG. 14) opposite the top surface 436, a first side surface 440, and a second side surface 442 (see FIG. 13) opposite the first side surface 440. The first horizontal wedge 430 has a vertical wedge surface 444 at the first end 430. The vertical wedge surface 444 of the first horizontal wedge 430 is oriented such that, when the first horizontal wedge 430 is placed adjacent the first vertical wedge 370, the vertical wedge surface 444 of the first horizontal wedge 430 abuts the second vertical wedge surface 386 of the first vertical wedge 370, the top surface 436 of the first horizontal wedge 430 is aligned with the top surface 376 of the first vertical wedge 370, the bottom surface 438 of the first horizontal wedge 430 is aligned with the bottom surface 378 of the first vertical wedge, the first side surface 440 of the first horizontal wedge 430 is aligned with the first side surface 380 of the first vertical wedge, and the second side surface 442 of the first horizontal wedge 430 is aligned with the second side surface 382 of the first vertical wedge 370. The first horizontal wedge 430 has a horizontal wedge surface 446 at its second end 434. The horizontal wedge surface 446 of the first horizontal wedge 430 is oriented such that, when the first horizontal wedge 430 is positioned adjacent the wedge body 320 with the bottom surface 438 of the first horizontal wedge 430 abutting the bottom wall 320 of the wedge body 320 and the first side surface 440 of the first horizontal wedge 430 abutting the first side wall 328 of the wedge body 320, the horizontal wedge surface 446 of the first horizontal wedge 430 abuts the first horizontal wedge surface 336 of the wedge body 320. A horizontal slot 448 (see FIG. 13) extends through the first horizontal wedge 430 from the first end 432 of the first horizontal wedge 430 to the second end 434 of the first horizontal wedge 430. The horizontal slot 448 of the first horizontal wedge 430 is horizontally oblong. A hole 450 (see FIG. 13) extends from the horizontal slot 448 of the first horizontal wedge 430 to the first side surface 440 of the first horizontal wedge 430.

Continuing to refer to FIGS. 8 through 12, in an embodiment, the wedge 310 includes a second horizontal wedge 460 having a first end 462, a second end 464 opposite the first end 462, a top surface 466, a bottom surface 468 opposite the top surface 466, a first side surface 470, and a second side surface 472 (see FIG. 13) opposite the first side surface 470. The second horizontal wedge 460 has a horizontal wedge surface 474 at the first end 462. The horizontal wedge surface 474 of the second horizontal wedge 460 is oriented such that, when the second horizontal wedge 460 is positioned adjacent the wedge body 320 with the bottom surface 468 of the first second wedge 460 abutting the bottom wall 326 of the wedge body 320 and the first side surface 470 of the second horizontal wedge 460 abutting the first side wall 328 of the wedge body 320, the horizontal wedge surface 474 of second first horizontal wedge 460 abuts the second horizontal wedge surface 338 of the wedge body 320. The second horizontal wedge 460 has a vertical wedge surface 476 at the second end 464. The vertical wedge surface 476 of the second horizontal wedge 460 is oriented such that, when the second horizontal wedge 460 is placed adjacent the second vertical wedge 400, the vertical wedge surface 476 of the second horizontal wedge 460 abuts the first vertical wedge surface 414 of the second vertical wedge 400, the top surface 466 of the of the of the second horizontal wedge 460 is aligned with the top surface 406 of the second vertical wedge 400, the bottom surface 468 of the second horizontal wedge 460 is aligned with the bottom surface 408 of the second vertical wedge 400, the first side surface 470 of the second horizontal wedge 460 is aligned with the first side surface 410 of the second vertical wedge 400, and the second side surface 472 of the second horizontal wedge 460 is aligned with the second side surface 412 of the second vertical wedge 400. A horizontal slot 478 extends through the second horizontal wedge 460 from the first end 462 of the first horizontal wedge 460 to the second end 464 of the first horizontal wedge 460. The horizontal slot 478 of the second horizontal wedge 460 is horizontally oblong. A hole 480 (see FIG. 13) extends from the horizontal slot 478 of the first horizontal wedge 460 to the first side surface 470 of the first horizontal wedge 460.

Continuing to refer to FIGS. 8 through 12, in an embodiment, the wedge 310 includes an end wedge 490 a first end 492, a second end 494 opposite the first end 492, and a vertical wedge surface 496 at the first end 492. An axial hole 498 extends through the end wedge 490 from the first end 492 of the end wedge 490 to the second end 494 of the end wedge 490 (see FIG. 11). An internal thread 500 extends along at least part of the axial hole 498 of the end wedge 490. The vertical wedge surface 496 of the end wedge 490 is oriented such that, when the end wedge 490 is placed adjacent the second vertical wedge 400 with the vertical wedge surface 496 of the end wedge 490 abutting the second vertical wedge surface 416 of the second vertical wedge 400, the axial hole 498 of the end wedge 490 aligns with the vertical slot 418 of the second vertical wedge 400.

Continuing to refer to FIGS. 8 through 12, in an embodiment, the wedge 310 includes an operator 510 that is installed within the axial hole 358 of the front wedge 350. A through slot 512 extends axially through the operator 510 (see FIG. 12). In an embodiment, the through slot 512 has a hexagonal cross-section. A groove 514 extends around the operator 510.

Continuing to refer to FIGS. 8 through 12, in an embodiment, the wedge 310 includes a stud operator 520. The stud operator 520 includes an operator torque portion 522 that is inserted within the through slot 512 of the operator 510 in a manner such that the stud operator 520 may move axially with respect to the operator 510 but may not rotate with respect to the operator 510 (see FIG. 12). The stud operator 520 includes a ratchet torque portion 524 that is positioned opposite the operator torque portion 522. The ratchet torque portion 524 includes a plurality of ramped torque applying surfaces 526 that are positioned and oriented so as to apply torque when the stud operator 520 is rotated in a first direction. The ratchet torque portion 520 includes a plurality of flat torque applying surfaces 528 that are positioned and oriented so as to apply torque when the stud operator 520 is rotated in a second direction that is opposite the first direction. In an embodiment, the ratchet torque portion 524 includes four of the ramped torque applying surfaces 526 and four of the flat torque applying surfaces 528. In other embodiments, the ratchet torque portion 524 may include more or fewer than four of the ramped torque applying surfaces 526 and may include more or fewer than four of the flat torque applying surfaces 528.

Continuing to refer to FIGS. 8 through 12, in an embodiment, the wedge 310 includes an elongated head ratchet 540 having a first end 542 and a second end 544 opposite the first end 542. The head ratchet 540 is sized and shaped so as to extend through the axial hole 358 of the front wedge 350, the vertical slot 388 of the first vertical wedge 370, the horizontal slot 448 of the first horizontal wedge 430, the axial hole 340 of the middle portion 334 of the wedge body 310, the horizontal slot 478 of the second horizontal wedge 460, the vertical slot 418 of the second vertical wedge 400, and the axial hole 498 of the end wedge 490. A head 546 is formed at the first end 542 of the head ratchet 540 (see FIG. 12). The head 546 is sized and shaped such that, when the head ratchet 540 is inserted through the axial hole 358 of the front wedge 350, the head 546 cannot pass through the narrowed portion 366 of the axial hole 358 of the front wedge 350, and bears on the flange 364 of the front wedge 350. The head ratchet 540 includes an interface portion 548 that is located on the head 546 of the head ratchet 540 and is configured to engage the ratchet torque portion 524 of the stud operator 520 such that, when the interface portion 548 of the head ratchet 540 engages the ratchet torque portion 524 of the stud operator 520, rotation of the stud operator 520 causes corresponding rotation of the head ratchet 540.

Continuing to refer to FIGS. 8 through 12, the interface portion 548 includes a first plurality of flat torque receiving surfaces 550 that is positioned and oriented so as to receive a torque applied in a first direction, and a second plurality of flat torque receiving surfaces 552 that is positioned and oriented so as to receive a torque applied in a second direction that is opposite the first direction. In an embodiment, the first plurality of flat torque receiving surfaces 550 includes four of the flat torque receiving surfaces 550 and the second plurality of flat torque receiving surfaces 552 includes four of the flat torque receiving surfaces 552. In other embodiments, the first plurality of flat torque receiving surfaces 550 may include more or fewer than four of the flat torque receiving surfaces 550 and the second plurality of flat torque receiving surfaces 552 may include more or fewer than four of the flat torque receiving surfaces 552. The head ratchet 540 includes first and second threaded portions 554, 556 and an intermediate portion 558 between the first and second threaded portions 554, 556. The second threaded portion 556 of the head ratchet 540 is located adjacent the second end 544 of the head ratchet 540. The first threaded portion 554 of the head ratchet 540 is located intermediate the first and second ends 542, 544 of the head ratchet 540. The first threaded portion 554 is sized and shaped so as to threadedly engage the internal threads 500 of the axial hole 498 of the end wedge 490. The intermediate portion 558 of the head ratchet 540 has an outer diameter that is smaller than those of each of the first and second threaded portions 554, 556 of the head ratchet 540.

Continuing to refer to FIGS. 8 through 12, in an embodiment, the wedge 310 includes a nut 570 having an internal thread 572 that is configured to threadedly engage the second threaded portion 556 of the head ratchet 540. The nut 570 is sized and shaped such that it does not fit within the axial hole 498 of the end wedge 490.

Continuing to refer to FIGS. 8 through 12, in an embodiment, the wedge 310 includes a first compression spring 580 that is sized and shaped so as to be placed over the operator torque portion 522 of the stud operator 520. In an embodiment, the wedge 310 includes a second compression spring 582 that is sized and shaped so as to be placed over the intermediate portion 558 of the head ratchet 540.

Continuing to refer to FIGS. 8 through 12, in an embodiment, the wedge 310 includes first, second, third, and fourth leaf springs 590, 592, 594, 596. The first leaf spring 590 is configured so as to be positioned within the hole 390 of the first vertical wedge 370 so as to bias the first vertical wedge 370 to a position abutting the wedge body 320. The second leaf spring 592 is configured so as to be positioned within the hole 420 of the second vertical wedge 400 so as to bias the second vertical wedge 400 to a position abutting the wedge body 320. The third leaf spring 594 is configured so as to be positioned within the hole 420 of the first horizontal wedge 400 so as to bias the first horizontal wedge 400 to a position abutting the wedge body 320. The fourth leaf spring 596 is configured so as to be positioned within the hole 450 of the second horizontal wedge 430 so as to bias the second horizontal wedge 430 to a position abutting the wedge body 320.

Continuing to refer to FIGS. 8 through 12, in an embodiment, the wedge 310 includes first and second wires 600, 602. In an embodiment, each of the first and second wires 600, 602 is configured to be positioned within a corresponding one of the first and second transverse wire holes 360, 362 of the front wedge 350 so as to retain various elements of the wedge 310 in an operative relationship to one another as will be described in detail hereinafter.

Continuing to refer to FIGS. 8 through 12, assembly of the wedge 310 is described. The head ratchet 540 is inserted into the axial hole 358 of the front wedge 350 until the head 546 of the head ratchet 540 abuts the flange 364 of the front wedge 350. The first compression spring 580 is placed over the operator torque portion 522 of the stud operator 520 and the stud operator 520 is inserted into the axial hole 358 of the front wedge 350 until the stud operator 520 abuts the head ratchet 540. The operator 510 is inserted into the axial hole 358 of the front wedge 350 with the operator torque portion 522 of the stud operator positioned within the through slot 512 of the operator 510. The operator 510 is positioned such that the groove 514 of the operator 510 is aligned with the first and second transverse wire holes 360, 362 of the front wedge 350, and the first and second wires 600, 602 are inserted into and secured within the corresponding ones of the first and second transverse wire holes 360, 362 of the front wedge 350 so as to retain the operator 510 within the front wedge 350. As a result, the operator 510, the first compression spring 580, the stud operator 520, the head ratchet 540, and the front wedge 350 are secured to one another, with the second end 544 of the head ratchet 540 extending past the second end 354 of the front wedge 350.

Continuing to refer to FIGS. 8 through 12, the portion of the head ratchet 540 that extends from the front wedge 350 is inserted, sequentially, through the vertical slot 388 of the first vertical wedge 370, the horizontal slot 448 of the first horizontal wedge 430, the axial hole 340 of the wedge body 320, the horizontal slot 478 of the second horizontal wedge 460, the vertical slot 418 of the second vertical wedge 400, the axial hole 498 of the end wedge 490 (with the first threaded portion 554 of the head ratchet 540 threadedly engaging the internal threads 500 of the axial hole 498 of the end wedge 490), and the second compression spring 582, and is secured at its second end 544 by threadedly engaging the second threaded portion 556 of the head ratchet 540 to the internal thread 572 of the nut 570.

Continuing to refer to FIGS. 8 through 12, the first leaf spring 590 is positioned within the hole 390 of the first vertical wedge 370 and retained within the hole 390 and between the bottom wall 326 of the wedge body 320 and the head ratchet 540 so as to bias the first vertical wedge 370 to a position abutting the wedge body 320. The second leaf spring 592 is positioned within the hole 420 of the second vertical wedge 400 and retained within the hole 420 and between the bottom wall 326 of the wedge body 320 and the head ratchet 540 so as to bias the second vertical wedge 400 to a position abutting the wedge body 320. In this regard, the first leaf spring 590 is positioned such that motion of the first vertical wedge 370 away from the bottom wall 326 of the wedge body 320 compresses the first leaf spring 590 between the first vertical wedge 370 and the head ratchet 540. Consequently, the first leaf spring 590 urges the first vertical wedge 370 away from the head ratchet 540 and toward the bottom wall 326 of the wedge body 320. The second leaf spring 592 operates in a similar manner. Because the vertical slots 388, 418 of the first and second vertical wedges 370, 400 are vertically oblong, the first and second vertical wedges 370, 400 are able to move vertically (i.e., toward and away from to the bottom wall 326 of the wedge body 320), but are not able to move horizontally (i.e., toward and away from the first side wall 328 of the wedge body 320).

Continuing to refer to FIGS. 8 through 12, the third leaf spring 594 is positioned within the hole 450 of the first vertical wedge 430 and is retained within the hole 450 and between the first side wall 328 of the wedge body 320 and the head ratchet 540 so as to bias the first horizontal wedge 430 to a position abutting the wedge body 320. The fourth leaf spring 596 is positioned within the hole 480 of the second horizontal wedge 460 and is retained within the hole 480 and between the first side wall 328 of the wedge body 320 and the head ratchet 540 so as to bias the second horizontal wedge 460 to a position abutting the wedge body 320. In this regard, the second leaf spring 594 is positioned such that motion of the first horizontal wedge 430 away from the first side wall 328 of the wedge body 320 compresses the third leaf spring 594 between the first horizontal wedge 430 and the head ratchet 540. Consequently, the third leaf spring 594 urges the first horizontal wedge 430 away from the head ratchet 540 and toward the first side wall 328 of the wedge body 320. The fourth leaf spring 594 operates in a similar manner. Because the horizontal slots 448, 478 of the first and second vertical wedges 430, 460 are horizontally oblong, the first and second horizontal wedges 430, 460 are able to move horizontally (i.e., toward and away from the first side wall 328 of the wedge body 320), but are not able to move vertically (i.e., toward and away from the bottom wall 326 of the wedge body 320).

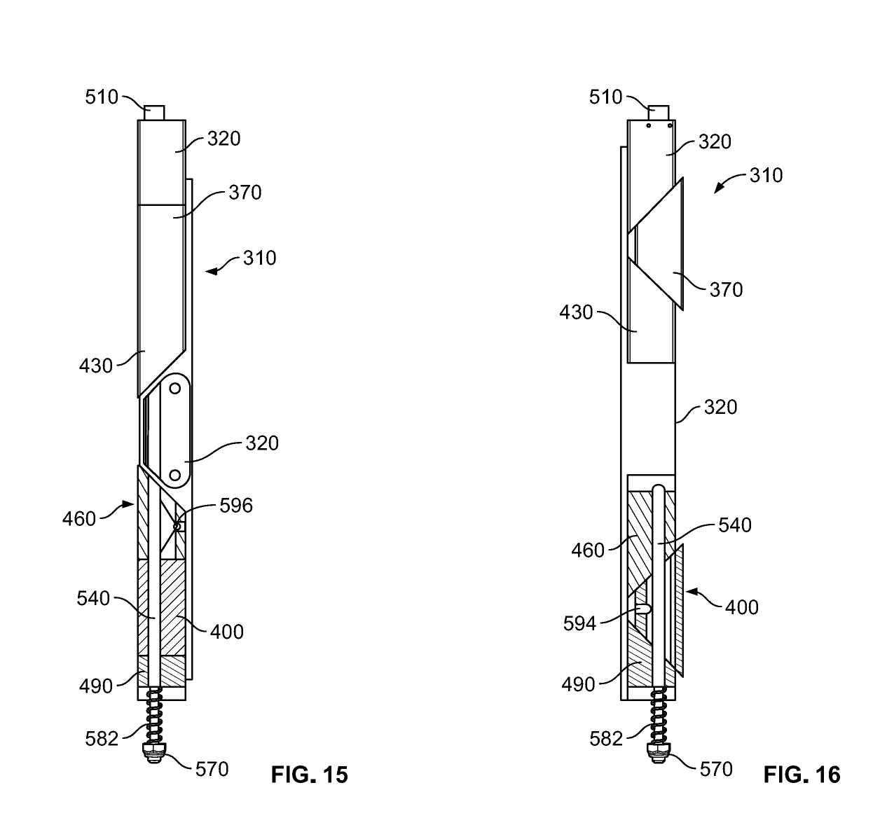

Referring now to FIGS. 13 through 16, operation of the wedge 310 in an expanding direction is described. FIGS. 13 and 14 show top and front cross-sectional views, respectively, of the wedge 310 while positioned in a relaxed position. FIGS. 15 and 16 show top and front cross-sectional views, respectively, of the wedge 310 while positioned in an expanded position. A user inserts an appropriate tool into the slot 512 of the operator 510. For example, in an embodiment in which the slot 512 is hexagonal, a hex key may be an appropriate tool. The user rotates the tool in a first direction within the slot 512, thereby rotating the operator 510. As described above, the operator torque portion 522 of the stud operator 520 is received within the slot 512 of the operator 510. As a result, rotation of the operator 510 causes corresponding rotation of the stud operator 520. The clockwise rotation of the operator 510 and the stud operator 520 corresponds to the first direction of torque described above with reference to the stud operator 520 and the head ratchet 540. As a result, clockwise rotation of the stud operator 520 drives the ramped torque applying surfaces 526 of the stud operator 520 against the flat torque receiving surfaces 550 of the head ratchet 540, causing commensurate clockwise rotation of the head ratchet 540.

Continuing to refer to FIGS. 13 through 16, rotation of the head ratchet 540 causes the head ratchet 540 to move in a direction toward the end wedge 490 within the vertical slot 388 of the first vertical wedge 370, the horizontal slot 448 of the first horizontal wedge 430, the axial hole 340 of the wedge body 320, the horizontal slot 478 of the second horizontal wedge 460, the vertical slot 418 of the second vertical wedge 400, and the axial hole 498 of the end wedge 490 due to the threaded engagement of the first threaded portion 554 of the head ratchet 540 with the internal threads 500 of the axial hole 498 of the end wedge 490. Because the head 546 of the head ratchet 540 abuts the flange 364 of the front wedge 350, the axial motion of the head ratchet 540 drives corresponding axial motion of the front wedge 350 along the wedge body 320 in a direction toward the end wedge 490. As a result, the axial distance between the front wedge 350 and the end wedge 490 is constricted. The front wedge 350, first vertical wedge 370, and first horizontal wedge 430 are compressed toward the first horizontal wedge surface 336 of the wedge body 310, while the end wedge 490, the second vertical wedge 400, and the second horizontal wedge 460 are compressed toward the second horizontal wedge surface 338 of the wedge body 310.

Continuing to refer to FIGS. 13 through 16, due to the engagements between the vertical wedge surface 356 of the front wedge and the first vertical wedge surface 382 of the first vertical wedge 370, between the second vertical wedge surface 386 of the first vertical wedge 370 and the vertical wedge surface 444 of the first horizontal wedge 430, and between the horizontal wedge surface 446 of the first horizontal wedge 430 and the first horizontal wedge surface 336 of the wedge body 320, such compression urges the first vertical wedge 370 and the first horizontal wedge 430 away from the wedge body 320. More particularly, the first vertical wedge 370 is urged away from the wedge body 320 in a vertical direction (see FIGS. 14 and 16), while the first horizontal wedge 430 is urged away from the wedge body 320 in a horizontal direction (see FIGS. 13 and 15), such that they move toward the expanded position shown in FIGS. 15 and 16. By the same operation, the second vertical wedge 400 and the second horizontal wedge 460 are also urged away from the wedge body 320 in a vertical direction and a horizontal direction, respectively. Once a predefined maximum torque has been reached, the ramped torque applying surfaces 526 of the stud operator 520 will disengage from the flat torque receiving surfaces 550 of the head ratchet 540, rather than applying further torque thereto. As a result, the stud operator 520 disengages from the head ratchet 540, and further advancement of the head ratchet 530 is prevented.

Continuing to refer to FIGS. 13 through 16, operation of the wedge 310 in a relaxing direction is described. A user inserts an appropriate tool into the slot 512 of the operator 510. For example, in an embodiment in which the slot 512 is hexagonal, a hex key may be an appropriate tool. The user rotates the tool in a counterclockwise direction within the slot 512, thereby rotating the operator 510. As described above, the operator 510 and the stud operator 520 rotate together. The counterclockwise rotation of the operator 510 and the stud operator 520 corresponds to the second direction of torque described above with reference to the stud operator 520 and the head ratchet 540. As a result, counterclockwise rotation of the stud operator 520 drives the flat torque applying surfaces 528 of the stud operator 520 against the flat torque receiving surfaces 552 of the head ratchet 540, causing commensurate counterclockwise rotation of the head ratchet 540. Such rotation of the head ratchet 540 causes the head ratchet 540 to move axially with respect to the wedge body 320 in a directly away from the end wedge 490 due to the threaded engagement of the first threaded portion 554 of the head ratchet 540 with the internal threads 500 of the axial hole 498 of the end wedge 490.

Continuing to refer to FIGS. 13 through 16, the first leaf spring 590 urges the first vertical wedge 370 toward the bottom wall 326 of the wedge body 320, the second leaf spring 592 urges the second vertical wedge 400 toward the bottom wall 326 of the wedge body 320, the third leaf spring 594 urges the first horizontal wedge 430 toward the first side wall 328 of the wedge body, and the fourth leaf spring 596 urges the second horizontal wedge 460 toward the first side wall 328 of the wedge body 320. Due to such urging, the front wedge 350, the first vertical wedge 370, and the first horizontal wedge 430 spread apart along the wedge body 320 (i.e., away from the first horizontal wedge surface 336 of the wedge body 320) once the axial force upon the front wedge 350 by the head ratchet 540 is relieved. Similarly, due to such urging, the end wedge 490, the second vertical wedge 400, and the second horizontal wedge 460 spread apart along the wedge body 320 (i.e., away from the second horizontal wedge surface 338 of the wedge body 320) once the axial force upon the end wedge 490 by the head ratchet 540 is relieved. Torquing may continue in this manner until first threaded portion 554 of the head ratchet 540 is disengaged from the internal thread 500 of the axial hole 498 of the end wedge 490. After such disengagement, the intermediate portion 558 of the head ratchet 540 floats within the axial hole 498 of the end wedge 490, but the various elements of the wedge 310 are retained in place by the nut 570, which prevents the head ratchet 540 from being removed and from passing through the various elements of the wedge 310, and by the first and second wires 600, 602, which are aligned with the groove 514 of the operator 500 and prevent the operator 500 from being removed from the front wedge 350. At this point, the wedge 310 is in its relaxed position, as shown in FIGS. 13 and 14.

It should be understood that the embodiments described herein are merely exemplary in nature and that a person skilled in the art may make many variations and modifications thereto without departing from the scope of the present invention. All such variations and modifications, including those discussed above, are intended to be included within the scope of the invention.

What is claimed is:

1. A device comprising:
a body having a first end, a second end opposite the first end, a middle portion between the first and second ends, a longitudinal axis, and a hole extending axially through at least a portion of the body along the longitudinal axis thereof;
a front wedge having a hole extending therethrough and a face, the front wedge being positioned at the first end of the body such that the hole of the front wedge is aligned with the hole of the body;
a body wedge having a first face and a second face, the body wedge being positioned adjacent the front wedge and adjacent the body, the first face of the body wedge being flush with the face of the front wedge, wherein the first face of the body wedge and the face of the front wedge are configured such that motion of the front wedge toward the second end of the body causes motion of the body wedge away from the body in a first direction that is perpendicular to the longitudinal axis;
a ratchet having an interface portion and a threaded portion, the ratchet being positioned within the hole of the body and within the hole of the front wedge, the ratchet and the hole of the front wedge being sized and shaped such that motion of the ratchet along the longitudinal axis of the body toward the second end of the body causes corresponding motion of the front wedge along the longitudinal axis of the body toward the second end of the body; and
an internal thread configured to receive threadedly the threaded portion of the ratchet, whereby rotation of the ratchet with respect to the body about the longitudinal axis in a first direction causes the ratchet to move toward the second end of the body, and whereby rotation of the ratchet with respect to the body about the longitudinal axis in a second direction opposite the first direction causes the ratchet to move away from the second end of the body.

2. The device of claim 1, further comprising a stud operator positioned within the hole of the front wedge and adjacent to the interface portion of the ratchet, wherein the stud operator and the ratchet are configured such that rotation of the stud operator with respect to the body about the longitudinal axis in the second direction drives corresponding rotation of the ratchet with respect to the body about the longitudinal axis in the second direction.

3. The device of claim 2, wherein the ratchet includes at least one torque receiving surface, wherein the stud operator includes at least one torque applying surface, and wherein the at least one torque applying surface of the stud operator and the at least one torque receiving surface of the ratchet are oriented obliquely to one another.

4. The device of claim 3, further comprising a front operator positioned within the hole of the front wedge; and
a spring positioned within the hole of the front wedge and intermediate the front operator and the stud operator, the spring being configured to urge the stud operator toward the ratchet,
wherein the spring, the at least one torque receiving surface of the ratchet, and the at least one torque applying surface of the stud operator cooperate to produce the threshold torque.

5. The device of claim 1, further comprising at least one attachment point configured for attaching the device to an underlying structure.

6. The device of claim 1, wherein the face of the front wedge is a ramped face that is inclined with respect to the longitudinal axis of the body, wherein the first face of the body wedge is a ramped face that is inclined with respect to the longitudinal axis of the body, and wherein the second face of the body wedge is a ramped face that is inclined with respect to the longitudinal axis of the body.

7. The device of claim 2, wherein the stud operator and the ratchet are configured such that rotation of the stud operator with respect to the body about the longitudinal axis in the first direction with an applied torque that is less than a threshold torque drives corresponding rotation of the ratchet with respect to the body about the longitudinal axis in the first direction, and such that rotation of the stud operator with respect to the body about the longitudinal axis in the first direction with an applied torque that is greater than the threshold torque causes the stud operator to rotate with respect to the ratchet and does not cause corresponding rotation of the ratchet with respect to the body about the longitudinal axis in the first direction.

8. The device of claim 1, further comprising a middle wedge having a first face, a second face opposite the first face of the middle wedge, and a slot extending through the middle wedge from the first face of the middle wedge to the second face of the middle wedge, the slot being configured to receive the body therein,
wherein the body is positioned within the slot of the middle wedge such that the middle wedge is aligned with the middle portion of the body and such that the first face of the middle wedge abuts the second face of the body wedge.

9. The device of claim 8, wherein the device is configured such that motion of the front wedge toward the second end of the body forces the front wedge against the body wedge and forces the body wedge against the middle wedge, whereby the front wedge and the middle wedge press against the body wedge from opposite sides, and whereby the pressure exerted on the body wedge by the front wedge, the pressure exerted on the body wedge by the middle wedge, engagement between the face of the front wedge and the first face of the body wedge, and engagement between the first face of the middle wedge and the second face of the body wedge cooperate to urge the body wedge away from the body in the first direction.

10. The device of claim 9, further comprising an end wedge attached to the second end of the body, the end wedge including a face that is inclined with respect to the longitudinal axis of the body; and
a second body wedge having a first face, a second face opposite the first face of the second body wedge, and a slot extending through the second body wedge from the first face of the second body wedge to the second face of the second body wedge, the body being received within the slot of the second body wedge, the second body wedge being positioned adjacent the end wedge, the first face of the second body wedge being flush with the second face of the middle wedge, and the second face of the second body wedge being flush with the face of the end wedge,
wherein the first face of the second body wedge, the second face of the second body wedge, the second face of the middle wedge, and the face of the end wedge are configured such motion of the middle wedge toward the second end of the body causes motion of the second body wedge away from the body in the first direction.

11. The device of claim 8, further comprising a spring positioned intermediate the body wedge and the body, the spring being configured so as to resist movement of the body wedge away from the body in the first direction.

12. The device of claim 8, wherein the internal thread is formed within the hole of the body.

13. The device of claim 8, wherein the face of the front wedge is a ramped face that is inclined with respect to the longitudinal axis of the body, wherein the first face of the body wedge is a ramped face that is inclined with respect to the longitudinal axis of the body, wherein the second face of the body wedge is a ramped face that is inclined with respect to the longitudinal axis of the body, wherein the first face of the middle wedge is a ramped face that is inclined with respect to the longitudinal axis of the body, and wherein the second face of the middle wedge is a ramped face that is inclined with respect to the longitudinal axis of the body.

14. The device of claim 1, further comprising a side wedge a having a first face, a second face opposite the first face of the side wedge, and a passage extending through the side wedge from the first face of the side wedge to the second face of the side wedge, the side wedge being positioned adjacent the body wedge and adjacent the body such that the first face of the side wedge is flush with the second face of the body wedge,
wherein the middle portion of the body has a first face facing generally toward the first end of the body and a second face opposite the first face of the middle portion of the body and facing generally toward the second end of the body.

15. The device of claim 14, wherein the second face of the body wedge, the first face of the middle portion of the body, the first face of the side wedge, and the second face of the side wedge are configured such that when the side wedge is positioned adjacent the body wedge and adjacent the body, motion of the front wedge toward the second end of the body causes motion of the side wedge away from the body in a second direction that is perpendicular to the longitudinal axis and perpendicular to the first direction.

16. The device of claim 15, further comprising:
an end wedge having a hole extending therethrough and a face, wherein the internal thread is formed within the hole of the end wedge;
a second body wedge having a first face, a second face opposite the first face of the second body wedge, and a hole extending through the second body wedge from the first face of the second body wedge to the second face of the second body wedge; and
a second side wedge having a first face, a second face opposite the first face of the second side wedge, and a hole extending through the second side wedge from the first face of the second side wedge to the second face of the second side wedge,
wherein the second side wedge is positioned adjacent the body such that the first face of the second side wedge is flush with the second face of the middle portion of the body and such that the hole of the second side wedge is aligned with the longitudinal axis of the body,
wherein the second body wedge is positioned adjacent the body such that the first face of the second body wedge is flush with the second face of the second side wedge and such that the hole of the second body wedge is aligned with the longitudinal axis of the body, and
wherein the end wedge is positioned adjacent the body such that the face of the end wedge is flush with the second face of the second body wedge and such that the hole of the end wedge is aligned with the longitudinal axis of the body.

17. The device of claim 16, wherein the second face of the middle portion of the body, the first face of the second side wedge, the second face of the second side wedge, and the first face of the second body wedge are configured such that motion of the end wedge toward the first end of the body causes motion of the second side wedge away from the body in the second direction, and
wherein the second face of the second side wedge, the first face of the second body wedge, the second face of the second body wedge, and the face of end wedge are configured such that motion of the end wedge toward the first end of the body causes motion of the second body wedge away from the body in the first direction.

18. The device of claim 14, wherein the threads of the ratchet engage threadedly the internal thread of the hole of the end wedge, whereby advancement of the ratchet causes motion of the front wedge toward the second end of the body and causes motion of the end wedge toward the first end of the body.

19. The device of claim 14, further comprising a spring positioned intermediate the body and the side wedge and configured so as to resist movement of the side wedge away from the body in the second direction.

20. The device of claim 14, wherein the face of the front wedge is a ramped face that is inclined with respect to the longitudinal axis of the body, wherein the first face of the body wedge is a ramped face that is inclined with respect to the longitudinal axis of the body, wherein the second face of the body wedge is a ramped face that is inclined with respect to the longitudinal axis of the body, wherein the first face of the side wedge is a ramped face that is inclined with respect to the longitudinal axis of the body, wherein the second face of the side wedge is a ramped face that is inclined with respect to the longitudinal axis of the body, wherein the first face of the middle portion of the body is a ramped face that is inclined with respect to the longitudinal axis of the body, and wherein the second face of the middle portion of the body is a ramped face that is inclined with respect to the longitudinal axis of the body.
